(19) United States
(12) Patent Application Publication
(10) Pub. No.: US 2026/0173631 A1
(43) Pub. Date: Jun. 18, 2026

(54) TRANSPARENT DISPLAY

(71) Applicant: AUO Corporation, Hsinchu City (TW)

(72) Inventors: Jia-Long WU, Hsinchu City (TW); Yu-Tang TSAI, Hsinchu City (TW); Kun-Cheng TIEN, Hsinchu City (TW)

(21) Appl. No.: 19/393,377

(22) Filed: Nov. 18, 2025

(30) Foreign Application Priority Data
Dec. 12, 2024 (TW) 113148346

(51) Int. Cl. H10H 29/855; H10H 29/49

(52) U.S. Cl. CPC H10H 29/855; H10H 29/49

(57) ABSTRACT

A transparent display includes a plurality of light-permeable sections, a plurality of horizontal line strips, a plurality of vertical line strips, and a plurality of driving electrode sections. The driving electrode sections are connected to the horizontal and the vertical line strips. The horizontal line strips, the vertical line strips, and the driving electrode sections which are arranged in a mesh along horizontal auxiliary lines and vertical auxiliary lines surround the light-permeable sections. The driving electrode sections have at least one first edge and at least one second edge apiece. The first and the second edges extend along a first and a second straight line respectively. The first and the second straight lines are not parallel. Neither the first straight line nor the second straight line is parallel to the horizontal and the vertical auxiliary lines.

### CROSS-REFERENCE TO RELATED APPLICATION

This application claims priority to Taiwan Application Serial Number 113148346, filed December 12, 2024, which is herein incorporated by reference in its entirety.

### BACKGROUND

### TECHNICAL FIELD

The present disclosure relates to a display. More particularly, the present disclosure relates to a transparent display.

### DESCRIPTION OF RELATED ART

A conventional transparent display has a circuit pattern layer, which is usually distributed in a display area of the transparent display and has many sections capable of emitting light. Theses sections have low light transmittance apiece, thereby obstructing light. Hence, each of the sections has a small size, so as to reduce undesired influence on the overall light transmittance of the transparent display. However, these sections usually cause light diffraction, resulting in reducing quality of image of the transparent display due to the light diffraction.

### SUMMARY

The disclosure according to at least one embodiment provides a transparent display that can reduce the intensity of noise with at least one high-frequency term, thereby improving quality of image.

At least one embodiment according to the present disclosure provides a transparent display including a plurality of light-permeable sections, a plurality of horizontal line strips, a plurality of vertical line strips, and a plurality of driving electrode sections. The horizontal line strips extend along a plurality of horizontal auxiliary lines that are arranged side by side, where a portion of the horizontal line strips is distributed along one of the horizontal auxiliary lines. The vertical line strips extend along a plurality of vertical auxiliary lines that are arranged side by side, where a portion of the vertical line strips is distributed along one of the vertical auxiliary lines. An extending direction of each of the horizontal auxiliary lines is different from an extending direction of each of the vertical auxiliary lines. The driving electrode sections are connected to the horizontal line strips and the vertical line strips. The horizontal line strips, the vertical line strips, and the driving electrode sections are arranged in a mesh along the horizontal auxiliary lines and the vertical auxiliary lines, while the horizontal line strips, the vertical line strips, and the driving electrode sections surround the light-permeable sections. Each of the driving electrode sections has at least one first edge and at least one second edge. The first edge extends along the first straight line. The second edge extends along the second straight line. The intersection of the first straight line with the horizontal auxiliary line forms a first acute angle, while the intersection of the second straight line with the horizontal auxiliary line forms a second acute angle.

The first and second edges of each of the driving electrode sections extend along the first straight line and the second straight line respectively, while the first straight line and the second straight line intersect with the horizontal auxiliary lines to form the first acute angle and the second acute angle respectively, so that the first edge and the second edge run neither parallel nor perpendicularly to any one of the horizontal line strips and the vertical line strips. Therefore, all of edges of each of the light-permeable sections extend in at least three directions, so as to attenuate the noise with at least one high-frequency term, thereby reducing the intensity of the previous noise with the high-frequency term and thus improving the quality of image.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows.

FIG. 1A is a top view of a transparent display according to at least one embodiment of this disclosure.

FIG. 1B is an enlarged view of a portion of FIG. 1A.

FIG. 1C is a schematic diagram of a diffraction pattern generated by the transparent display in FIG. 1A.

FIG. 2A is a top view of a transparent display in a comparative example.

FIG. 2B is a schematic diagram of a diffraction pattern generated by the transparent display in FIG. 2A.

FIG. 3 is a top view illustrating a comparison between the circuit pattern layers of FIG. 1B and FIG. 2A.

FIG. 4A is a top view of a transparent display according to at least one embodiment of this disclosure.

FIG. 4B is an enlarged view of a portion of FIG. 4A.

FIG. 4C is a schematic diagram of a diffraction pattern generated by the transparent display in FIG. 4A.

FIG. 5A is a top view of a transparent display according to at least one embodiment of this disclosure.

FIG. 5B is a schematic diagram of a diffraction pattern generated by the transparent display in FIG. 5A.

FIG. 6 is a top view of a transparent display according to at least one embodiment of this disclosure.

FIG. 7 is a top view of a transparent display according to at least one embodiment of this disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following description, in order to clearly present the technical features of the present disclosure, the dimensions (such as length, width, thickness, and depth) of elements (such as layers, films, substrates, and areas) in the drawings will be enlarged in unusual proportions, and the quantity of some elements will be reduced. Accordingly, the description and explanation of the following embodiments are not limited to the quantity, sizes and shapes of the elements presented in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case which are mainly for illustration are intended neither to accurately depict the actual shape of the elements nor to limit the scope of patent applications in this case.

Moreover, the words, such as “about”, “approximately”, or “substantially”, appearing in the present disclosure not only cover the clearly stated values and ranges, but also include permissible deviation ranges as understood by those with ordinary knowledge in the technical field of the invention. The permissible deviation range can be caused by the error generated during the measurement, where the error is caused by such as the limitation of the measurement system or the process conditions. In addition, “about” may be expressed within one or more standard deviations of the values, such as within ±30%, ±20%, ±10%, or ±5%. The word “about”, “approximately” or “substantially” appearing in this text can choose an acceptable deviation range or a standard deviation according to optical properties, etching properties, mechanical properties or other properties, not just one standard deviation to apply all the optical properties, etching properties, mechanical properties and other properties.

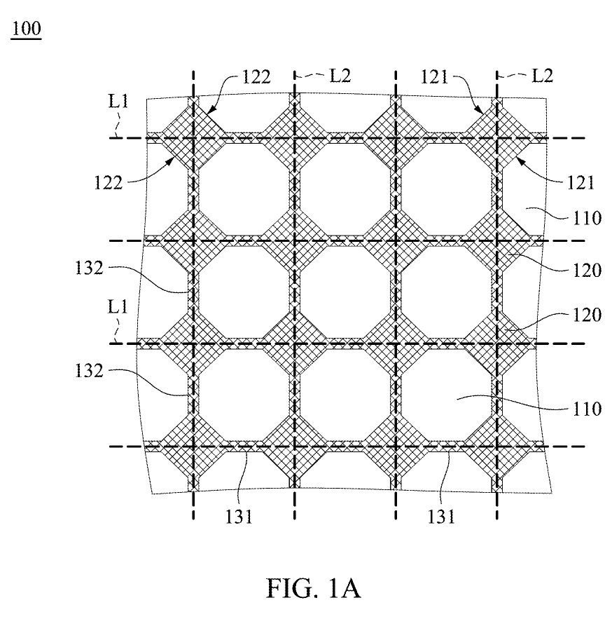

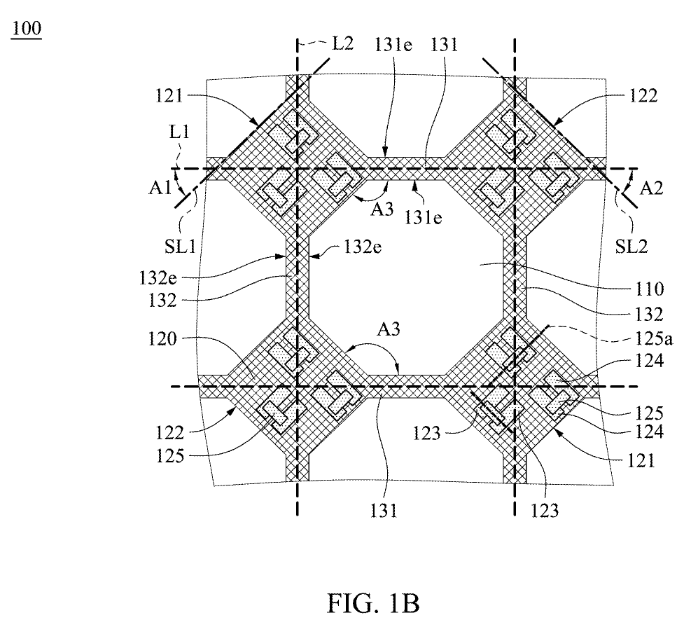

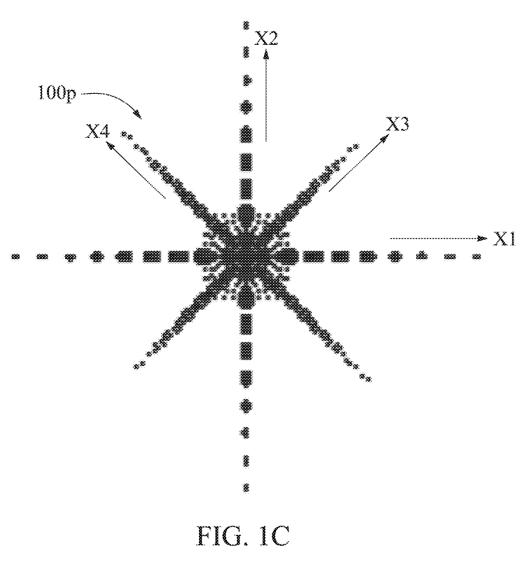

FIG. 1A is a top view of a transparent display according to at least one embodiment of this disclosure. Referring to FIG. 1A, a transparent display 100 includes a plurality of light-permeable sections 110, a plurality of driving electrode sections 120, a plurality of horizontal line strips 131, and a plurality of vertical line strips 132. The driving electrode sections 120, the horizontal line strips 131, and the vertical line strips 132 are all elements of circuit pattern layers of the transparent display 100 and have low light transmittance apiece. The light transmittance of the driving electrode section 120, the horizontal line strip 131, and the vertical line strips 132 can range between 0% and 10%. Each of the light-permeable sections 110 has high light transmittance which ranges, for example, between 50% and 95%. Hence, light (such as visible light) can pass through the light-permeable sections 110 almost completely, so that the light-permeable sections 110 have a transparent appearance apiece.

The horizontal line strips 131 extend along a plurality of horizontal auxiliary lines L1 that are arranged side by side, while the vertical line strips 132 extend along a plurality of vertical auxiliary lines L2 that are arranged side by side. The horizontal auxiliary line L1 and the vertical auxiliary line L2 can be regarded as an imaginary straight line apiece. That is, the transparent display 100 actually can show no horizontal auxiliary line L1 and no vertical auxiliary line L2. The extending direction of each horizontal auxiliary line L1 is different from the extending direction of each vertical auxiliary line L2. Taking FIG. 1A for example, the horizontal auxiliary lines L1 and the vertical auxiliary lines L2 are perpendicular to each other, while these horizontal auxiliary lines L1 and these vertical auxiliary lines L2 are arranged in a mesh.

In the embodiment as shown in FIG. 1A, a portion of the horizontal line strips 131 is distributed along one of the horizontal auxiliary lines L1, while a portion of the vertical line strips 132 is distributed along one of the vertical auxiliary lines L2. That is to say, multiple horizontal line strips 131 are distributed along one of the horizontal auxiliary lines L1, while multiple vertical line strips 132 are distributed along one of the vertical auxiliary lines L2. Taking FIG. 1A for example, some horizontal line strips 131 are distributed along one horizontal auxiliary line L1, while some vertical line strips 132 are distributed along one vertical auxiliary line L2. These driving electrode sections 120 are distributed at multiple intersections of the horizontal auxiliary lines L1 and the vertical auxiliary lines L2. Hence, the horizontal line strips 131, the vertical line strips 132, and the driving electrode sections 120 are arranged in a mesh along the horizontal auxiliary lines L1 and the vertical auxiliary lines L2, while the driving electrode sections 120 are arranged in an array.

In other words, the horizontal line strips 131, the vertical line strips 132, and the driving electrode sections 120 form a mesh pattern and surround the light-permeable sections 110, so that the light-permeable sections 110 are located within the lattices of the mesh pattern. Taking FIG. 1A for example, each of the light-permeable sections 110 can be surrounded by two horizontal line strips 131, two vertical line strips 132, and four driving electrode sections 120.

The driving electrode sections 120 are connected to the horizontal line strips 131 and the vertical line strips 132, where each of the driving electrode sections 120 is connected to two horizontal line strips 131 and two vertical line strips 132, so that each of the driving electrode sections 120 is located between two adjacent horizontal line strips 131, and between two adjacent vertical line strips 132. Accordingly, the vertical line strips 132 and the horizontal line strips 131 are separated by the driving electrode sections 120. For example, one driving electrode section 120 not only separates two adjacent vertical line strips 132, but also separates two adjacent horizontal line strips 131, as shown in FIG. 1A.

Each of the driving electrode sections 120 has at least one first edge 121 and at least one second edge 122, in which at least one first edge 121 is connected to one of the horizontal line strips 131 and one of the vertical line strips 132, while at least one second edge 122 is connected to one of the horizontal line strips 131 and one of the vertical line strips 132. Taking FIG. 1A for example, each of the driving electrode sections 120 has two opposite first edges 121 and two opposite second edges 122.

In a single driving electrode section 120, each first edge 121 is connected to one horizontal line strip 131 and one vertical line strip 132, while each second edge 122 is connected to one horizontal line strip 131 and one vertical line strip 132. At least one horizontal line strip 131 is connected between adjacent first edge 121 and second edge 122, and at least one vertical line strip 132 is connected between adjacent first edge 121 and second edge 122.

FIG. 1B is an enlarged view of a portion of FIG. 1A. Referring to FIG. 1A and FIG. 1B, in each of the driving electrode sections 120, at least one first edge 121 extends along the first straight line SL1, while at least one second edge 122 extends along the second straight line SL2, in which the first straight line SL1 is not parallel to the second straight line SL2. In the present embodiment, each of the first edges 121 extends along the first straight line SL1, while each of the second edges 122 extends along the second straight line SL2, where the first straight line SL1 may be perpendicular to the second straight line SL2. Both the first edge 121 and the second edge 122 can take the shape of a straight line apiece.

The first straight line SL1 and the second straight line SL2 are neither parallel nor perpendicular to each horizontal auxiliary line L1 and each vertical auxiliary line L2, so that any one of the first straight line SL1 and the second straight line SL2 intersects with the horizontal auxiliary line L1 and the vertical auxiliary lines L2. The first edge 121 and the second edge 122 of the driving electrode section 120 run also neither parallel nor perpendicular to any one of the horizontal line strips 131 and the vertical line strips 132. The intersection of the first straight line SL1 with the horizontal auxiliary line L1 forms a first acute angle A1, while the intersection of the second straight line SL2 with the horizontal auxiliary line L1 forms a second acute angle A2. In addition, the first straight line SL1 and the second straight line SL2 can be imaginary lines. That is to say, the transparent display 100 actually can show no first straight line SL1 and no second straight line SL2.

Each of the first acute angle A1 and the second acute angle A2 may range between 35 degrees and 55 degrees, such as 35 degrees or 55 degrees. That is, any one of the first acute angle A1 and the second acute angle A2 may range within 45±10 degrees. In the present embodiment, the horizontal line strips 131 and the vertical line strips 132 both are in the shape of a straight strip apiece, in which each of the horizontal line strips 131 has a pair of horizontal linear edges 131e, and each of the vertical line strips 132 has a pair of vertical linear edges 132e. Since each light-permeable section 110 is surrounded by two horizontal line strips 131, two vertical line strips 132, and four driving electrode sections 120, the edges of each light-permeable section 110 are defined by two horizontal linear edges 131e, two vertical linear edges 132e, two first edges 121 and two second edges 122.

Since the first edge 121 and the second edge 122 run neither parallel nor perpendicular to any one of the horizontal line strips 131 and the vertical line strips 132, the edges (equivalent to the first edge 121, the second edge 122, the horizontal linear edges 131e, and the vertical linear edges 132e) of each light-permeable section 110 are arranged to define a geometric shape that is a polygon with more than four sides, where all of the edges of each light-permeable section 110 extend in at least three directions. For example, all of the edges of the octagonal light-permeable sections 110 as shown in FIG. 1B extend in four directions parallel to the horizontal line strip 131, the vertical line strip 132, the first straight line SL1, and the second straight line SL2, respectively.

Since each of the light-permeable sections 110 is in the shape of an octagon, the light-permeable sections 110 have eight interior angles A3 apiece, where any one of the interior angles A3 of the geometric shape (i.e., octagonal light-permeable section 110) is greater than or equal to 125 degrees. Among eight interior angles A3 of each light-permeable section 110, two interior angles A3 are located between the horizontal linear edge 131e and the first edge 121, another two interior angles A3 are located between the horizontal linear edge 131e and the second edge 122.

Moreover, it can be seen from FIG. 1B that the first acute angle A1 and the interior angle A3 which is located between the horizontal linear edge 131e and the first edge 121 can be supplementary angles, while the second acute angle A2 and the interior angle A3 which is located between the horizontal linear edge 131e and the second edge 122 can be supplementary angles. Since each first acute angle A1 and each second acute angle A2 may range between 35 degrees and 55 degrees, the interior angle A3 adjacent to the horizontal linear edge 131e may range between 125 degrees and 145 degrees, such as 125 degrees or 145 degrees.

The driving electrode sections 120 include a plurality of electrode pads 123 and 124 apiece, in which at least one of the electrode pads 123 and 124 extends in the direction along the first straight line SL1 or the second straight line SL2. Taking FIG. 1B for example, at least one of the electrode pads 123 and 124 extends in the direction parallel to the first straight line SL1 or the second straight line SL2. Each of the driving electrode sections 120 includes four electrode pads 124 and two electrode pads 123, in which each two of the four electrode pads 124 are disposed opposite to each other, and the two electrode pads 123 are disposed to each other.

Each of the electrode pads 123 extends in the direction of the first straight line SL1, while each of the electrode pads 124 extends in the direction of the second straight line SL2. Accordingly, in the present embodiment, at least two of the electrode pads, i.e., the electrode pads 123 and 124, extend in the directions of the first straight line SL1 and the second straight line SL2 respectively, as shown in FIG. 1B. In addition, in the present embodiment, for example, the direction of the first straight line SL1 is a direction parallel to the first straight line SL1, and the direction of the second straight line SL2 is a direction parallel to the second straight line SL2.

Each of the driving electrode sections 120 further includes a plurality of light emitting components 125, in which the light emitting components 125 are disposed on the electrode pads 123 and 124, and electrically connected to the electrode pads 123 and 124. Each of the light emitting components 125 is disposed on two adjacent electrode pads 123 or two adjacent electrode pads 124, in which each of light emitting components 125 is in the shape of a strip.

Among the electrode pads 123 and the light emitting component 125 disposed thereon, the axis 125a of the light emitting component 125 may not be parallel to the extension direction of the electrode pad 123 (i.e., the extension direction of the first straight line SL1). For example, the axis 125a of the light emitting component 125 is perpendicular to the extension direction of the electrode pad 123 and is parallel to the second straight line SL2. Likewise, among the electrode pads 124 and the light emitting component 125 disposes thereon, the axis 125a of the light emitting component 125 may not be parallel to the direction of the electrode pad 124 (i.e., the extension direction of the second straight line SL2). For example, the axis 125a of the light emitting component 125 is perpendicular to the extension direction of the electrode pad 124 and is parallel to the first straight line SL1.

The light emitting components 125 can be light emitting diodes (LEDSs), such as micro LEDs or mini LEDs. These light emitting components 125 can emit light with single color (such as white light or blue light). Alternatively, these light emitting components 125 can emit light with various colors (for example, including red light, green light, and blue light). Each of the driving electrode sections 120 further includes a plurality of electronic components (not shown), such as thin film transistors (TFTs) and passive components. These electronic components are electrically connected to the light emitting components 125 and control the light emitting components 125 shining, so that the transparent display 100 can show images.

Each of the driving electrode sections 120 includes a plurality of layer (not shown) in a stack, such as multiple metal pattern layers, at least one semiconductor pattern layer, a black matrix, and multiple insulation layers, in which the electronic components are made of these layer in a stack. The contours of the driving electrode sections 120, the horizontal line strips 131, and the vertical line strips 132 are jointly defined by the metal pattern layers, the semiconductor pattern layer, and the black matrix, so that the driving electrode sections 120 can exhibit significantly different light transmittance apiece, that is, the light transmittance at different portions of one driving electrode section 120 is obviously not constant.

It is necessary to note that FIG. 1A mainly depicts the contour of circuit pattern layer of the transparent display 100, i.e., the contours of the driving electrode sections 120, the horizontal line strips 131, and the vertical line strips 132. Moreover, FIG. 1A omits multiple elements of the driving electrode sections 120. That is, the electrode pads 123, 124 and the light emitting components 125 are omitted from FIG. 1A, in which the elements of the driving electrode sections 120 (i.e., the electrode pads 123, 124 and the light emitting components 125) are only depict in FIG. 1B.

FIG. 1C is a schematic diagram of a diffraction pattern generated by the transparent display in FIG. 1A. Referring to FIG. 1C, a diffraction pattern 100p shown in FIG. 1C is depicted according to light spots formed by irradiating the transparent display 100 with a light beam having considerable intensity, in which the light beam can come from at least one of LED, incandescent lamp, mercury-vapor lamp, fluorescent lamp, and laser. The diffraction pattern 100p is depicted by color inversion, so that the black areas shown in the diffraction pattern 100p represent the light spots generated by diffraction. In other words, FIG. 1C depicts the light spots of the diffraction pattern 100p in black.

Referring to FIGS. 1A and 1C, the diffraction pattern 100p is mainly formed by the diffraction which is generated by the contours of the driving electrode sections 120, the horizontal line strips 131, and the vertical line strips 132. In other words, the shape of the diffraction pattern 100p (i.e., the shapes and the distribution of light spots) is determined by the contour of the circuit pattern layer in the transparent display 100 (as shown in FIG. 1A).

Referring to FIG. 1B and FIG. 1C, since each of the light-permeable sections 110 is in the shape of a polygon with more than four sides, all of the edges of each of the light-permeable sections 110 extend in three or more than three directions. Taking the octagonal light-permeable sections 110 shown in FIG. 1B for example, all of the edges of each light-permeable section 110 extend in four directions parallel to the horizontal line strip 131, the vertical line strip 132, the first straight line SL1, and the second straight line SL2 respectively.

As a result, the diffraction pattern 100p generated by the transparent display 100 extend not only in a horizontal direction X1 and a vertical direction X2, but also in oblique directions X3 and X4. The oblique directions X3 and X4 not only are not parallel to each other, but also are neither parallel nor perpendicular to any one of the horizontal direction X1 and vertical direction X2. Thus, the noise of the diffraction pattern 100p with high-frequency term are distributed in the horizontal direction X1, the vertical direction X2, and the oblique directions X3 and X4, thereby forming the diffraction pattern 100p in the shape of an asterisk, as shown in FIG. 1C.

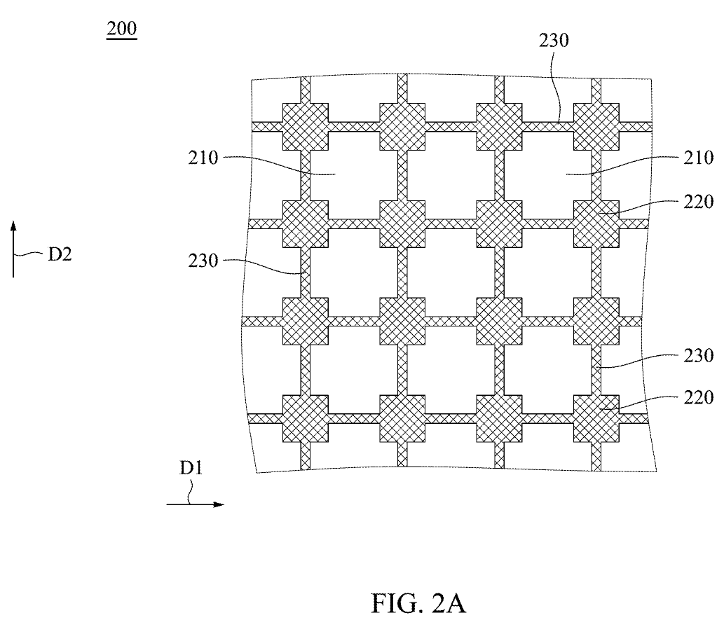

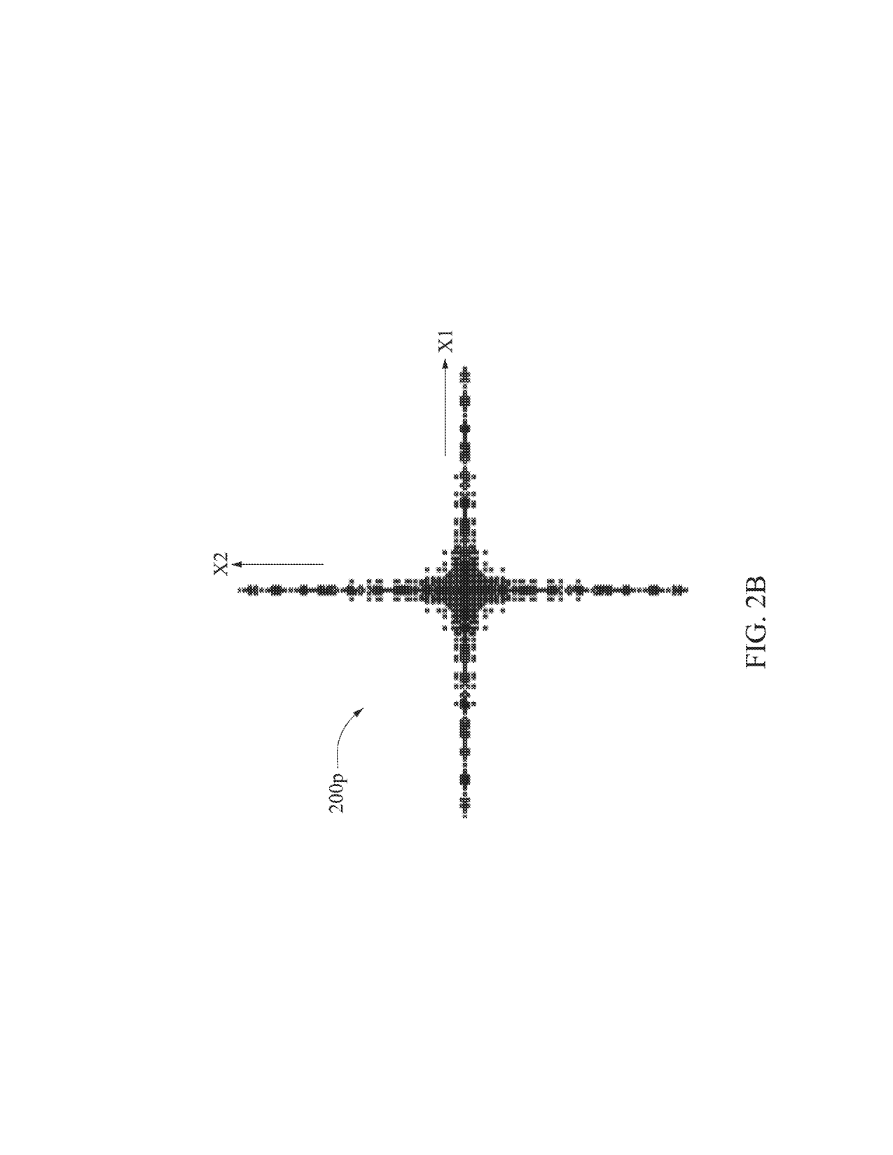

FIG. 2A is a top view of a transparent display in a comparative example. Referring to FIG. 2A, a transparent display 200 in the comparative example includes a plurality of cross-shaped light-permeable sections 210, a plurality of rectangular sections 220, and a plurality of line strips 230. The rectangular sections 220 and the line strips 230 are arranged in a mesh and surround these cross-shaped light-permeable sections 210, while the rectangular sections 220 are arranged in an array. The light transmittance of the rectangular sections 220 and the line strips 230 ranges between 0% and 10%, while the light transmittance of the cross-shaped light-permeable sections 210 ranges between 50% and 95%. Hence, the rectangular sections 220 and the line strips 230 have low light transmittance apiece, and the cross-shaped light-permeable sections 210 have high light transmittance apiece.

FIG. 2B is a schematic diagram of a diffraction pattern generated by the transparent display in FIG. 2A. Referring to FIG. 2B, a diffraction pattern 200p shown in FIG. 2B is also depicted according to light spots formed by irradiating transparent display 200 with the light beam having considerable intensity, in which the light beam can come from at least one of LED, incandescent lamp, mercury-vapor lamp, fluorescent lamp, and laser. In addition, the diffraction pattern 200p is depicted by color inversion, so FIG. 2B also depicts the light spots of the diffraction pattern 200p in black.

Referring to FIG. 2A and FIG. 2B, in the transparent display 200 of the comparative example, all of the edges of each cross-shaped light-permeable section 210 only extend in two directions. Taking FIG. 2A for example, the edges of the cross-shaped light-permeable sections 210 extend in a first direction D1 and a second direction D2, in which the first direction D1 is parallel to the horizontal auxiliary line L1 (referring to FIG. 1A), and the second direction D2 is parallel to the vertical auxiliary lines L2 (referring to FIG. 1A). Hence, the diffraction pattern 200p generated by the transparent display 200 mainly extends in the horizontal direction X1 and the vertical direction X2, so that the noise of the diffraction pattern 200p with high-frequency term is only distributed in the horizontal direction X1 and the vertical direction X2, thereby forming the cross-shaped diffraction pattern 200p as shown in FIG. 2B.

Referring to FIG. 1C and FIG. 2B, it can be known from the comparison between the diffraction pattern 100p of the present embodiment and the diffraction pattern 200p of the comparative example that the noise with high-frequency term of the diffraction pattern 200p in the comparative example is mainly distributed in two directions (i.e., the first direction D1 and the second direction D2), while the noise with high-frequency term of the diffraction pattern 100p in the present embodiment is clearly distributed in at least three directions (for example, four directions which are parallel to the horizontal line strip 131, the vertical line strip 132, the first straight line SL1, and the second straight line SL2 respectively).

As a result, in contrast to the diffraction pattern 200p of the comparative example, the noise with at least one high-frequency term of the diffraction pattern 100p in the present embodiment is more attenuated, so that the transparent display 100 of the present embodiment has significantly low intensity of noise with at least one high-frequency term, thereby achieving better quality of image more than that of the transparent display 200 in the comparative example. Hence, these light-permeable sections 110 in the present embodiment can reduce the influence of light diffraction on the transparent display 100, thereby improving the quality of image of the transparent display 100.

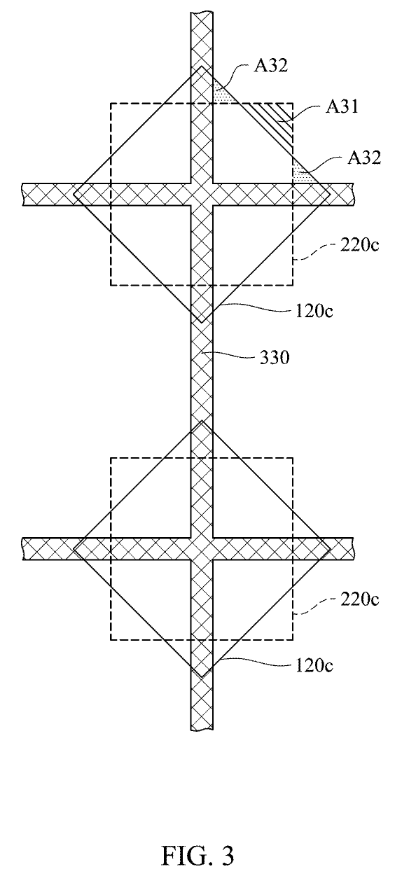

FIG. 3 is a top view illustrating a comparison between the circuit pattern layers of FIG. 1B and FIG. 2A, where FIG. 3 depicts the contours 120c of two driving electrode sections 120 (with solid lines) and depicts the contours 220c of two rectangular sections 220 (with dashed lines). These contours 120c overlap these contours 220c respectively. Moreover, FIG. 3 is drawn under the condition that the driving electrode section 120 and the rectangular section 220 have the same size and scale (such as the same area and equal sides). Thus, the contours 120c can be depicted by rotating the contours 220c.

FIG. 3 further depicts the mesh pattern 330 according to the horizontal line strips 131 and the vertical line strips 132 both in FIG. 1A, and the line strips 230 in FIG. 2A. FIG. 3 depicts the mesh pattern 330 under the condition that the widths of the horizontal line strips 131, the vertical line strips 132, and the line strips 230 are equal to each other, in which the portions of the mesh pattern 330 inside the contours 120c and 220c may be imaginary patterns. The portions of the mesh pattern 330 inside the contours 120c and 220c are depicted by the extensions of the horizontal line strip 131 and the vertical line strip 132. In fact, the horizontal line strip 131 cannot overlap or intersect the vertical line strip 132. Likewise, the line strips 230 also cannot overlap or intersect each other.

Referring to FIG. 3, the portion of the mesh pattern 330 inside the contours 120c and 220c can form a cross-shaped pattern, in which one cross-shaped pattern defines four quadrants. In FIG. 3, one large triangular area A31 and two small triangular areas A32 exist in the quadrant I which is defined by the upper cross-shaped pattern (and located at the upper right of the cross-shaped pattern), where the large triangular area A31 is marked with a diagonal pattern, and the small triangular area A32 is marked with a dotted pattern.

The large triangular areas A31 and the small triangular areas A32 are the regions where the mesh pattern 330 and the areas within both the contour 120c and the contour 220c do not overlap. Specifically, the large triangular areas A31 represent the portions of the rectangular sections 220 which do not overlap the driving electrode sections 120 and the mesh pattern 330, while the small triangular areas A32 represent the portions of the driving electrode sections 120 which do not overlap the rectangular sections 220 and the mesh pattern 330.

It can be known from FIG. 3 that under the condition that the driving electrode section 120 and the rectangular section 220 have the same size and scale, the region where the driving electrode section 120 (i.e., the area within the contour 120c) and the mesh pattern 330 overlap is larger than the region where the rectangular section 220 (i.e., the area within the contour 220c) and the mesh pattern 330 overlap, so that the size of one large triangular area A31 is larger than not only the size of one small triangular area A32, but also the total size of two small triangular areas A32.

As a result, in contrast to the rectangular section 220 of the comparative example, the driving electrode section 120 of the present embodiment occupies a relatively small area outside the mesh pattern 330, so that the size (e.g., area) of each light-permeable section 110 in the present embodiment is larger than the size (e.g., area) of each cross-shaped light-permeable section 210 in the comparative example. Accordingly, under the condition that the driving electrode section 120 and the rectangular section 220 have the same size and scale, the aperture ratio and the overall light transmittance of the transparent display 100 in the embodiment are larger than the aperture ratio and the overall light transmittance of the transparent display 200 in the comparative example.

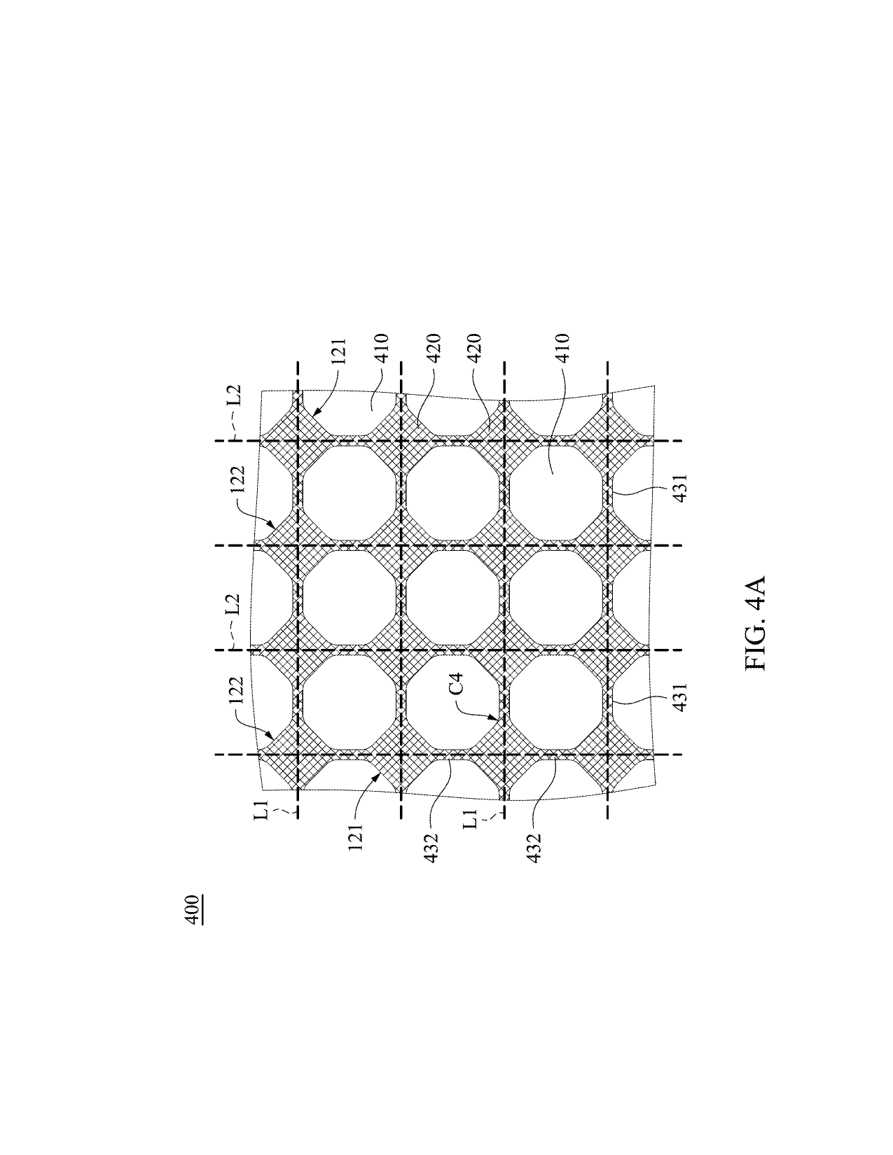

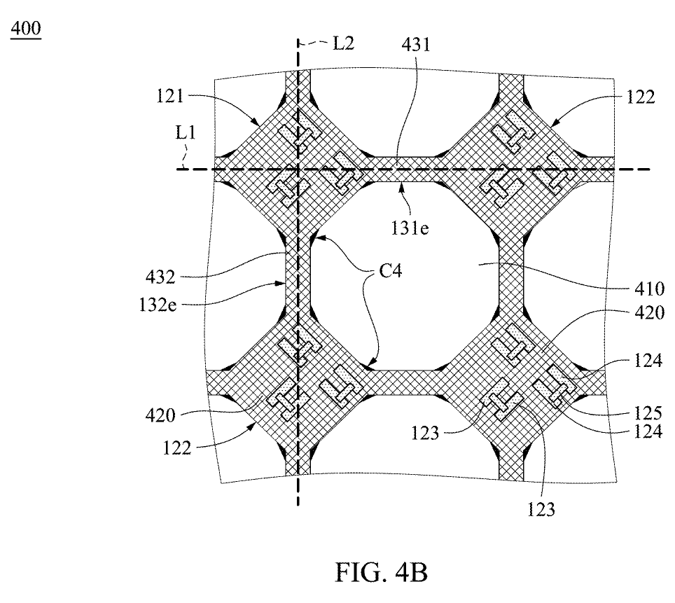

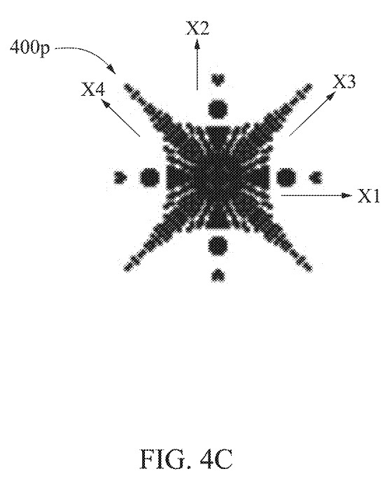

FIG. 4A is a top view of a transparent display according to at least one embodiment of this disclosure, and FIG. 4B is an enlarged view of a portion of FIG. 4A. Referring to FIG. 4A and FIG. 4B, a transparent display 400 in the present embodiment is similar to the transparent display 100 in the previous embodiment. For example, the transparent display 400 includes a plurality of light-permeable sections 410, a plurality of driving electrode sections 420, a plurality of horizontal line strips 431, and a plurality of vertical line strips 432.

The horizontal line strips 431 extend along the horizontal auxiliary lines L1, while the vertical line strips 432 extend along the vertical auxiliary lines L2, so that the horizontal line strips 431, the vertical line strips 432, and the driving electrode sections 420 are arranged in a mesh along the horizontal auxiliary lines L1 and the vertical auxiliary lines L2. Moreover, each of the driving electrode sections 420 also has two opposite first edges 121 and two opposite second edges 122. Each horizontal line strip 431 has a pair of opposite horizontal linear edges 131e, and each vertical line strip 432 has a pair of opposite vertical linear edges 132e.

The subsequent description primarily focuses on the difference between the transparent displays 100 and 400, while the same features of transparent displays 100 and 400 generally will not be described again. Specifically, unlike the transparent display 100 of the previous embodiment, in the transparent display 400 of the present embodiment, a curved edge C4 is formed between the edge of one of the horizontal line strips 431 and the vertical line strips 432, and the edge of one of the driving electrode sections 420 connected thereto.

Taking FIG. 4B for example, each of the first edges 121 is connected to one horizontal linear edge 131e and one vertical linear edge 132e, while each of the second edges 122 is also connected to one horizontal linear edge 131e and one vertical linear edge 132e. Among the vertical linear edge 132e, the first edge 121, and the horizontal linear edge 131e which are connected together, two curved edges C4 are formed between the vertical linear edge 132e and the first edge 121, and between the horizontal linear edge 131e and the first edge 121 respectively. Likewise, among the vertical linear edge 132e, the second edge 122, and the horizontal linear edge 131e which are connected together, another two curved edges C4 are formed between the vertical linear edge 132e and the second edge 122, and between the horizontal linear edge 131e and the second edge 122.

These curved edges C4 can be made of the black matrix. That is to say, the curved edge C4 may be the edge of the black matrix. The light-permeable sections 410 take the shape of an octagon apiece, while these curved edges C4 can make the light-permeable sections 410 in the shape of a round octagon apiece, so that each of the light-permeable sections 410 takes the shape of an approximate circle, as shown in FIGS. 4A and 4B.

FIG. 4C is a schematic diagram of a diffraction pattern generated by the transparent display in FIG. 4A, in which the methods of drawing FIGS. 4C and 1C are the same, while the method of generating the diffraction pattern 400p in FIG. 4C is the same as the method of generating the diffraction pattern 100p in FIG. 1C. Referring to FIGS. 4A and 4C, since each of the light-permeable sections 410 takes the shape of an approximate circle, the diffraction pattern 400p generated by the transparent display 400 not only extends in four directions along the horizontal direction X1, the vertical direction X2, and the oblique directions X3 and X4 respectively, but also has relatively short lengths in the previous four directions in contrast to the diffraction pattern 100p of FIG. 1C, so that the most light spot of the diffraction pattern 400p is concentrated and distributed at center. Hence, the transparent display 400 can allow more zero-order light to pass through.

As a result, the noise of the diffraction pattern 400p with high-frequency term can be more spread out or dissipated, while the transparent display 400 can allow more zero-order light to pass through, so that the transparent display 400 of the present embodiment has weaker noise with high-frequency term by using the curved edges C4. Accordingly, the light-permeable sections 410 can effectively reduce the influence of light diffraction on the transparent display 400, thereby improving the quality of image.

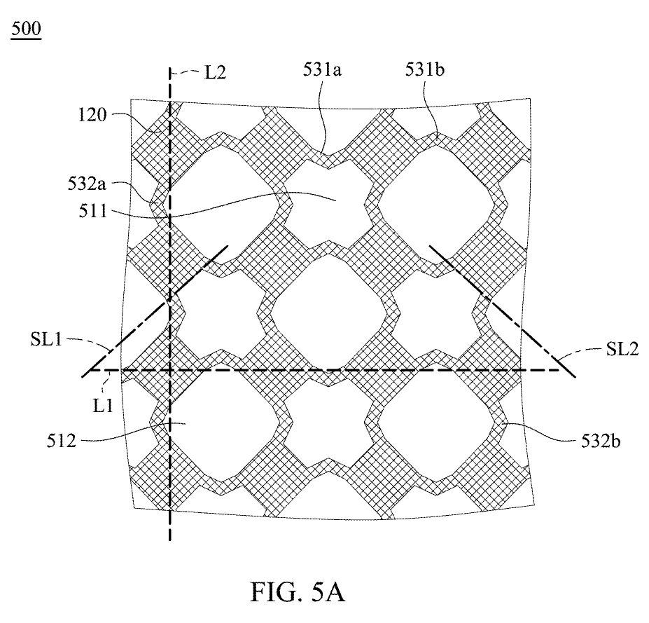

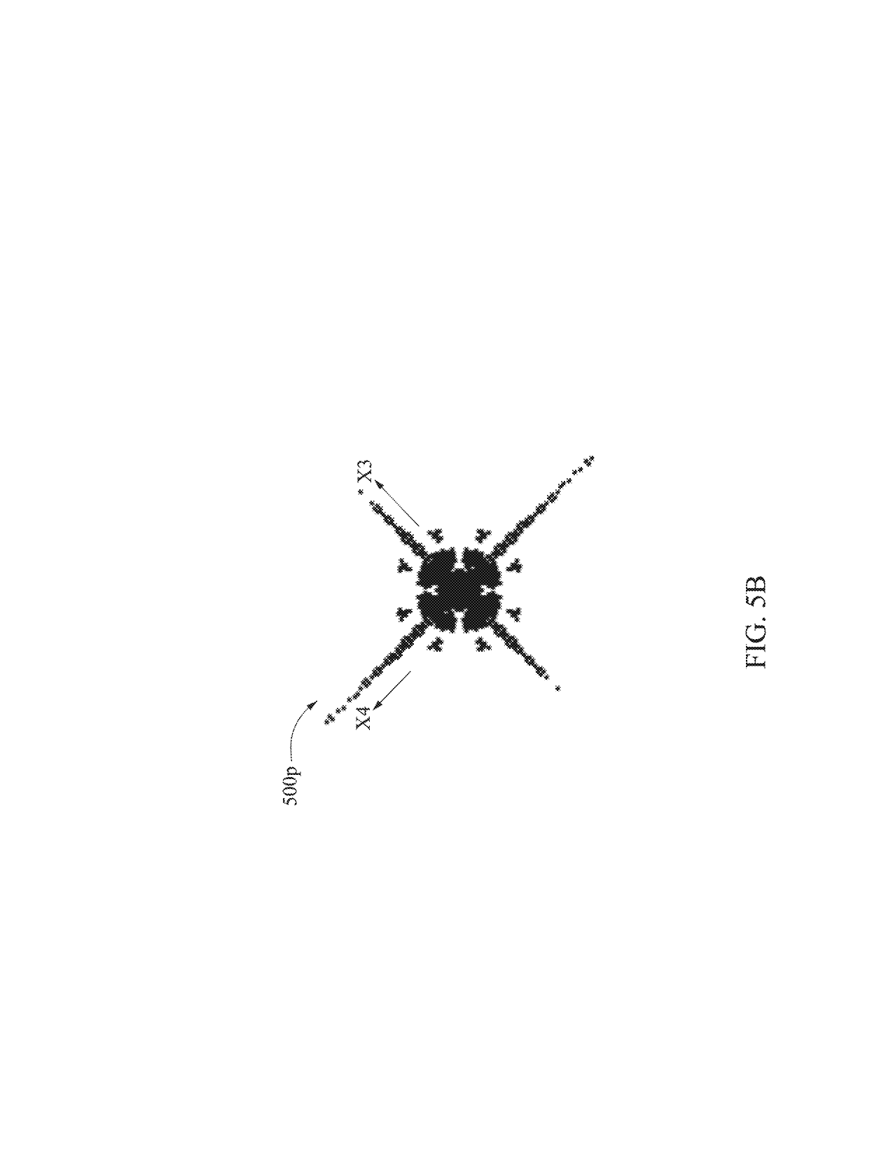

FIG. 5A is a top view of a transparent display according to at least one embodiment of this disclosure. Referring to FIG. 5A, a transparent display 500 of the present embodiment is similar to the transparent display 100 of the previous embodiment. For example, the transparent display 500 also includes a plurality of driving electrode sections 120. The subsequent description primarily focuses on the difference between the transparent displays 100 and 500, while the same features of transparent displays 100 and 500 generally will not be described again.

In contrast to the transparent display 100, the transparent display 500 further includes a plurality of horizontal line strips 531a, 531b, a plurality of vertical line strips 532a, 532b, and a plurality of light-permeable sections 511 and 512, in which at least one of the horizontal line strips 531a and 531b is in the shape of a curve or a polygonal chain, while at least one of the vertical line strips 532a and 532b is in the shape of a curve or a polygonal chain. Taking FIG. 5A for example, the horizontal line strips 531a and 531b look like a curve or a polygonal chain apiece, while the vertical line strips 532a and 532b look like a curve or a polygonal chain apiece, as shown in FIG. 5A.

The horizontal line strips 531a and 531b are different from each other, while the vertical line strips 532a and 532b are different from each other. In the embodiment as shown in FIG. 5A, the upper and lower edges of the horizontal line strip 531a are a concave edge and a convex edge respectively, while the lower and upper edges of the horizontal line strip 531b are a concave edge and a convex edge respectively. Likewise, the right and left edges of the vertical line strip 532a are a concave edge and a convex edge respectively, while the left and right edges of the vertical line strip 532b are a concave edge and a convex edge respectively.

These horizontal line strips 531a, 531b extend along the horizontal auxiliary lines L1, while these vertical line strips 532a, 532b extend along the vertical auxiliary lines L2. However, the horizontal line strips 531a and 531b are arranged alternately along the horizontal auxiliary line L1, while the vertical line strips 532a and 532b are arranged alternately along the vertical auxiliary line L2, thereby forming the light-permeable sections 511 and 512 with different shapes.

The edge of at least one of the light-permeable sections 511 and 512 is arranged to define an X-shape and surrounds the X-shape. The X-shape extends in a direction parallel to the first straight line SL1 and in a direction parallel to the second straight line SL2. Taking FIG. 5A for example, the light-permeable sections 511 take the shape of the X-shape apiece, while the X-shaped light-permeable section 511 extends in two directions parallel to the first straight line SL1 and the second straight line SL2 respectively. In addition, unlike the X-shaped light-permeable sections 511, each of the light-permeable sections 512 is in the shape of an approximate round rectangle, as shown in FIG. 5A.

FIG. 5B is a schematic diagram of a diffraction pattern generated by the transparent display in FIG. 5A, in which the methods of drawing FIGS. 5B and 1C are the same, while the method of generating the diffraction pattern 500p in FIG. 5B is the same as the method of generating the diffraction pattern 100p in FIG. 1C. Referring to FIGS. 5A and 5B, since each of the light-permeable sections 511 is in the shape of the X-shape, and each of the light-permeable sections 512 takes the shape of an approximate round rectangle, the diffraction pattern 500p generated by the transparent display 500 generally extends along the oblique directions X3 and X4. Moreover, the most light spot of the diffraction pattern 500p is concentrated and distributed at center, so that the transparent display 500 can allow more zero-order light to pass through, and spread out or dissipate the noise with high-frequency term, so as to attenuate the noise with high-frequency term, thereby achieving better quality of image.

It is worth mentioning that the horizontal line strips 431 and the vertical line strips 432 in FIG. 4A can be replaced by the horizontal line strips 531a, 531b and the vertical line strips 532a, 532b in FIG. 5A. In other words, the transparent display 500 in FIG. 5A also can have the curved edge C4 as shown in FIGS. 4A and 4B, so as to further spread out or dissipate the noise with high-frequency term, thereby improving the quality of image more.

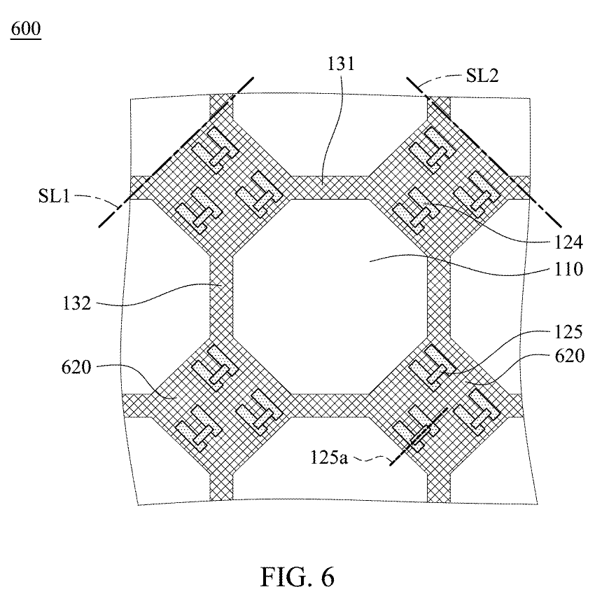

FIG. 6 is a top view of a transparent display according to at least one embodiment of this disclosure. Referring to FIG. 6, the transparent display 600 of the present embodiment includes a plurality of light-permeable sections 110, a plurality of driving electrode sections 620, a plurality of horizontal line strips 131, and a plurality of vertical line strips 132. The contours of the driving electrode sections 620 are the same as the contours of the driving electrode sections 120, so that the transparent display 600 also includes the octagonal light-permeable sections 110.

The transparent display 600 is similar to the transparent display 100 of the previous embodiment, where the difference between the transparent displays 600 and 100 is only that the arrangement of electrode pads of the driving electrode sections 620 and 120 is different. Specifically, the driving electrode section 620 shown in FIG. 6 includes a plurality of electrode pads 124 and a plurality of light emitting components 125, but does not include the electrode pads 123 as shown in FIG. 1B. Hence, all of the electrode pads 124 within each driving electrode section 620 extend in the direction parallel to the second straight line SL2.

The light emitting components 125 are disposed on the electrode pads 124 respectively and electrically connected to the electrode pads 124, in which the axis 125a of each light emitting component 125 is not parallel to the extension direction of the electrode pad 124 (i.e., the extension direction of the second straight line SL2). For example, the axis 125a is perpendicular to the extension direction of the electrode pad 124. In the embodiment shown in FIG. 6, the axis 125a of each light emitting component 125 can be parallel to the extension direction of the first straight line SL1.

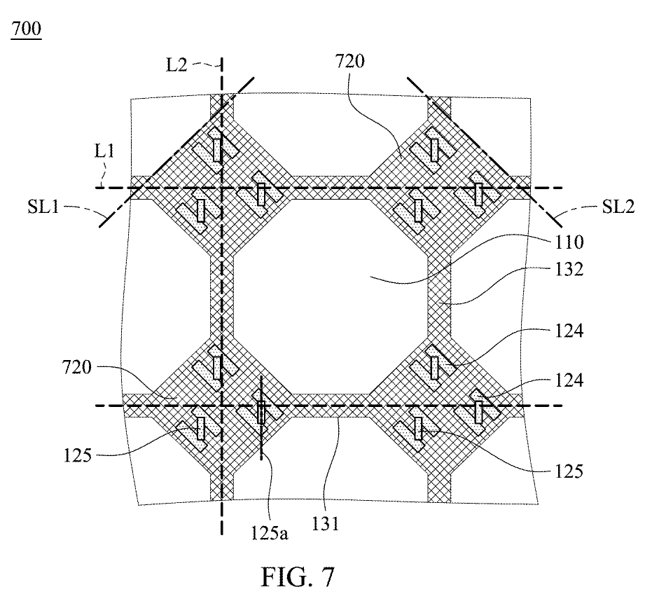

FIG. 7 is a top view of a transparent display according to at least one embodiment of this disclosure. Referring to FIG. 7, the transparent display 700 of the present embodiment includes a plurality of light-permeable sections 110, a plurality of driving electrode sections 720, a plurality of horizontal line strips 131, and a plurality of vertical line strips 132. The contours of the driving electrode sections 720 are the same as the contours of the driving electrode sections 120 and 620, so that the transparent display 700 also includes the octagonal light-permeable sections 110.

The transparent display 700 is similar to the transparent display 600 of the previous embodiment. For example, the driving electrode section 720 shown in FIG. 7 includes a plurality of electrode pads 124 and a plurality of light emitting components 125, in which the light emitting components 125 are disposed on the electrode pads 124 respectively and electrically connected to the electrode pads 124. The difference between the transparent displays 700 and 600 is that the arrangement of light emitting components 125 of the driving electrode sections 720 and 620 is different.

Specifically, in the transparent display 700, the axis 125a of each light emitting component 125 is parallel to the vertical auxiliary line L2 and perpendicular to the horizontal auxiliary line L1. Hence, the axis 125a is not parallel to any one of the first straight line SL1 and the second straight line SL2, and also not perpendicular to any one of the first straight line SL1 and the second straight line SL2.

It is particular to note that the arrangement of the electrode pads 123, 124 and the light emitting components 125 disclosed by FIGS. 6 and 7 can be used in the transparent display 400 of FIG. 4B and the transparent display 500 of FIG. 5A. Specifically, at least one driving electrode section 420 in FIG. 4B can be replaced by the driving electrode section 620 in FIG. 6 or the driving electrode section 720 in FIG. 7, while at least one driving electrode section 120 in FIG. 5A can be replaced by the driving electrode section 620 in FIG. 6 or the driving electrode section 720 in FIG. 7. Hence, the transparent displays 400 and 500 of the previous embodiments can employ the arrangement of the electrode pads 123, 124 and the light emitting components 125 in FIG. 6 or FIG. 7.

Therefore, the first edge and the second edge of each driving electrode section extend along the first straight line and the second straight line respectively, while the first edge and the second edge run neither parallel nor perpendicularly to any one of the horizontal line strips and the vertical line strips, so that all of the edges of each light-permeable section extend in at least three (such as four) directions, so as to attenuate the noise with at least one high-frequency term, thereby improving the quality of image.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A transparent display, comprising:
a plurality of light-permeable sections;
a plurality of horizontal line strips, extending along a plurality of horizontal auxiliary lines arranged side by side, wherein a portion of the horizontal line strips is distributed along one of the horizontal auxiliary lines;
a plurality of vertical line strips, extending along a plurality of vertical auxiliary lines arranged side by side, wherein a portion of the vertical line strips is distributed along one of the vertical auxiliary lines, and an extending direction of each of the horizontal auxiliary lines is different from an extending direction of each of the vertical auxiliary lines; and
a plurality of driving electrode sections, connected to the horizontal line strips and the vertical line strips, wherein the horizontal line strips, the vertical line strips, and the driving electrode sections are arranged in a mesh along the horizontal auxiliary lines and the vertical auxiliary lines, wherein the horizontal line strips, the vertical line strips, and the driving electrode sections surround the light-permeable sections, each of the driving electrode sections having at least one first edge and at least one second edge,
wherein the at least one first edge extends along a first straight line,
wherein the at least one second edge extends along a second straight line,
wherein an intersection of the first straight line with one of the horizontal auxiliary lines forms a first acute angle, while an intersection of the second straight line with one of the horizontal auxiliary lines forms a second acute angle.

2. The transparent display of claim 1, wherein each of the first acute angle and the second acute angle ranges between 35 degrees and 55 degrees.

3. The transparent display of claim 1, wherein an edge of each of the light-permeable sections is arranged to define a geometric shape, and the edge surrounds the geometric shape,
wherein the geometric shape has a plurality of interior angles, and any one of the interior angles is greater than or equal to 125 degrees.

4. The transparent display of claim 1, wherein each of the driving electrode sections comprises:
a plurality of electrode pads, wherein at least one of the electrode pads extends along the first straight line or the second straight line.

5. The transparent display of claim 4, wherein at least two of the electrode pads extend along the first straight line and the second straight line respectively.

6. The transparent display of claim 4, wherein each of the driving electrode sections further comprises:
a plurality of light emitting components, disposed on the electrode pads and electrically connected to the electrode pads.

7. The transparent display of claim 1, wherein a curved edge is formed between an edge of one of both the horizontal line strips and the vertical line strips, and an edge of one of the driving electrode sections connected thereto.

8. The transparent display of claim 1, wherein at least one of the horizontal line strips is in the shape of a curve or a polygonal chain.

9. The transparent display of claim 8, wherein at least one of the vertical line strips is in the shape of a curve or a polygonal chain.

10. The transparent display of claim 9, wherein an edge of at least one of the light-permeable sections is arranged to define an X-shape and surrounds the X-shape,
wherein the X-shape extends in a direction parallel to the first straight line and in a direction parallel to the second straight line.

11. A transparent display, comprising:
a plurality of light-permeable sections, wherein an edge of each of the light-permeable sections is arranged to define a geometric shape, and the edge surrounds the geometric shape, wherein the geometric shape has a plurality of interior angles, and any one of the interior angles is greater than or equal to 125 degrees;
a plurality of horizontal line strips, extending along a plurality of horizontal auxiliary lines arranged side by side, wherein a portion of the horizontal line strips is distributed along one of the horizontal auxiliary lines;
a plurality of vertical line strips, extending along a plurality of vertical auxiliary lines arranged side by side, wherein a portion of the vertical line strips is distributed along one of the vertical auxiliary lines, and an extending direction of each of the horizontal auxiliary lines is different from an extending direction of each of the vertical auxiliary lines; and
a plurality of driving electrode sections, connected to the horizontal line strips and the vertical line strips, wherein the horizontal line strips, the vertical line strips, and the driving electrode sections are arranged in a mesh along the horizontal auxiliary lines and the vertical auxiliary lines, wherein the horizontal line strips, the vertical line strips, and the driving electrode sections surround the light-permeable sections, each of the driving electrode sections having at least one first edge and at least one second edge,
wherein the at least one first edge extends along a first straight line,
wherein the at least one second edge extends along a second straight line,
wherein an intersection of the first straight line with one of the horizontal auxiliary lines forms a first acute angle, while an intersection of the second straight line with one of the horizontal auxiliary lines forms a second acute angle,
wherein each of the first acute angle and the second acute angle ranges between 35 degrees and 55 degrees.

12. The transparent display of claim 11, wherein each of the driving electrode sections comprises:
a plurality of electrode pads, wherein at least one of the electrode pads extends along the first straight line or the second straight line.

13. The transparent display of claim 12, wherein at least two of the electrode pads extend along the first straight line and the second straight line respectively.

14. The transparent display of claim 12, wherein each of the driving electrode sections further comprises:
a plurality of light emitting components, disposed on the electrode pads and electrically connected to the electrode pads.

15. The transparent display of claim 11, wherein a curved edge is formed between an edge of one of both the horizontal line strips and the vertical line strips, and an edge of one of the driving electrode sections connected thereto.
